(19) United States
(12) Patent Application Publication
(10) Pub. No.: US 2022/0371880 A1
(43) Pub. Date: Nov. 24, 2022

(54) PIEZOELECTRIC ACTUATOR STACK WITH TAPERED SIDEWALL

(71) Applicant: Microsoft Technology Licensing, LLC, Redmond, WA (US)

(72) Inventor: Risto Heikki MUTIKAINEN, Espoo (FI)

(73) Assignee: Microsoft Technology Licensing, LLC, Redmond, WA (US)

(21) Appl. No.: 17/324,945

(22) Filed: May 19, 2021

(51) Int. Cl. B81B 3/00; G02B 26/08; B81C 1/00

(52) U.S. Cl. CPC B81B 3/0021; G02B 26/0858; B81C 1/00103; B81B 2201/038; B81B 2203/0384; B81B 2203/04; B81C 2201/0132

(57) ABSTRACT

A piezoelectric actuator comprises a substrate, an insulator layer on the substrate, and a piezo actuator stack on the insulator layer. The piezo actuator stack comprises an insulator-adjacent electrode on the insulator layer. A piezo layer having a tapered sidewall resides on a portion of the insulator-adjacent electrode. An insulator-distal electrode on the piezo layer having a taper-adjacent edge offset from an intersection of the tapered sidewall of the piezo layer and the insulator-adjacent electrode.

### BACKGROUND

Piezoelectric actuators produce small amounts of displacement with a high force capability when a voltage is applied across the actuator. When multiple piezoelectric actuators are deployed in a device, they may be used to generate highly precise positioning of device components. Piezoelectric actuators are capable of producing a high force-to-volume ratio but their displacement may impact neighboring components that are less pliable.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

A piezoelectric actuator comprises a substrate, an insulator layer on the substrate, and a piezo actuator stack on the insulator layer. The piezo actuator stack comprises an insulator-adjacent electrode on the insulator layer. A piezo layer having a tapered sidewall resides on a portion of the insulator-adjacent electrode. An insulator-distal electrode on the piezo layer has a taper-adjacent edge offset from an intersection of the tapered sidewall of the piezo layer and the insulator-adjacent electrode.

### BRIEF DESCRIPTION OF THE DRAWINGS

FIG. 1A schematically shows an example piezo actuator stack.

FIG. 1B schematically shows an example piezoelectric actuator including the piezo actuator stack of FIG. 1A.

FIG. 2A schematically shows an example piezo actuator stack wherein the piezo layer has a tapered sidewall.

FIG. 2B schematically shows an example piezo actuator stack wherein the piezo layer has a tapered sidewall and the insulator-distal electrode is offset from the tapered sidewall of the piezo layer.

FIG. 2C is a scanning electron microscope image of a piezo layer having a tapered sidewall.

FIG. 3A schematically shows expected strain fields and deformation due to applied electric field for the piezo actuator stack of FIG. 1A.

FIG. 3B schematically shows expected strain fields and deformation due to applied electric field for the piezo actuator stack of FIG. 2A.

FIG. 3C schematically shows expected strain fields and deformation due to applied electric field for the piezo actuator stack of FIG. 2B.

FIG. 4 schematically shows expected electric fields within a piezoelectric actuator comprising the piezo actuator stack of FIG. 2B.

FIG. 5 is an example method for manufacturing a piezoelectric actuator.

FIG. 6 schematically shows an exemplary control system for a microelectromechanical system that includes one or more piezoelectric actuators.

FIG. 7 illustrates an example resonant scanning mirror system.

### DETAILED DESCRIPTION

Piezo actuators are commonly integrated into devices that rely on mechanical movement, such as micro-electro mechanical system (MEMS) devices. There are other means to drive movement in MEMS devices, such as electrostatic or magnetic forces, but piezo actuation generates a relatively high force among these activation means. Different classes of piezoelectric actuators can be used as sensors, actuators, power harvesters, or mechanical switches.

Piezo actuation is proportional to electric field which accordingly includes significant dimensional changes in accompanying structures. By applying a drive signal to the piezoelectric material within the actuator, controlled and predictable movements of a component coupled to the actuator can be generated.

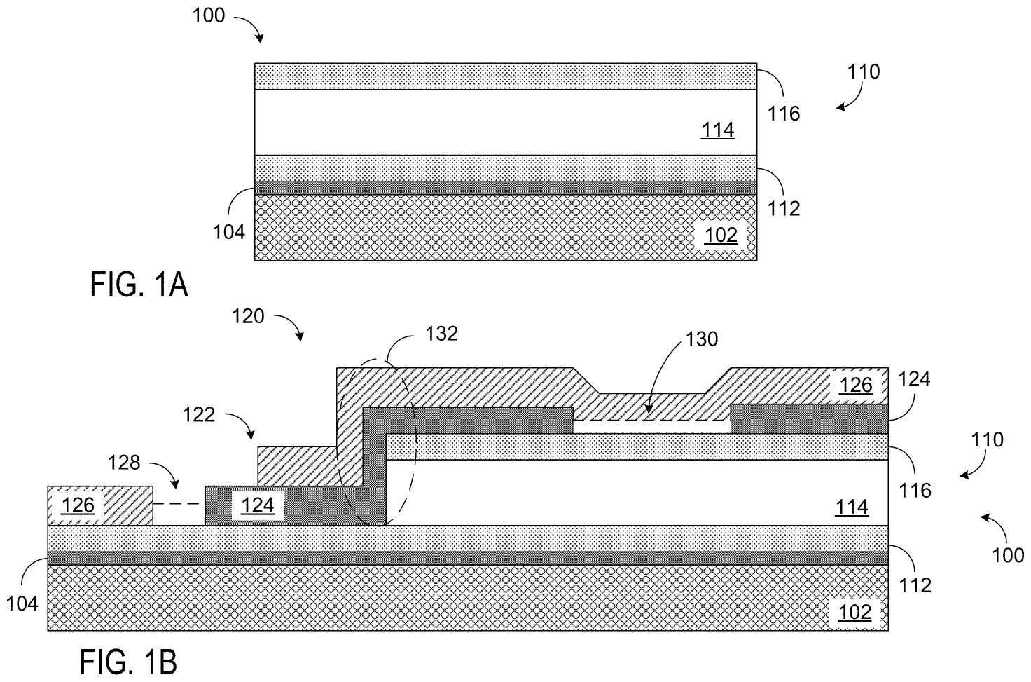

FIG. 1A schematically shows a cross section of a typical piezoelectric actuator 100. A substrate 102 is provided, which may take the form of a silicon wafer as one example. On the substrate 102 is an insulator layer 104, which may include an insulating oxide, e.g., silicon dioxide, having a width on the order of 0.1-1 μm in one example. Insulator layer 104 may additionally or alternatively include an adhesion promoter layer, such as TiO₂, Ti, TiW, etc.

A piezo actuator stack 110 is positioned on insulator layer 104. Piezo actuator stack 110 includes three layers—an insulator-adjacent electrode 112 on insulator layer 104, a piezo layer 114 on at least a portion of the insulator-adjacent electrode 112, and an insulator-distal electrode 116 on at least a portion of piezo layer 114. Both insulator-adjacent electrode 112 and insulator-distal electrode 116 may be relatively thin, for example 0.1 μm conductive films made of platinum, palladium, iridium, etc., or multilayered films such as Ti/Pt films. In some examples, electrically insulating interface films may be added to increase reliability of the electrodes, such as strontium ruthenium oxide (SRO).

In some examples, piezo actuator stack 110 may be placed directly on substrate 102, e.g., provided that insulator-adjacent electrode 112 and substrate 102 have similarly low potential. In many examples, a metallurgical insulator or buffer layer is provided to prevent intermixing of insulator-adjacent electrode 112 and substrate 102. In some examples, insulator layer 104 may itself possess some conductive properties. As such, while primarily described with relation to an insulating oxide, insulator layer 104 may include one or more insulators, buffers, films, adhesives, and/or other layers that promote the layering and operation of functional components onto substrate 102.

Piezo layer 114 may be any suitable piezoelectric ceramic material, such as PZT (lead zirconium titanite), PNZT (Niobium doped PZT), KNN (potassium sodium niobite), BNT (barium neodymium titanite), BNN (barium sodium niobite), BST (barium strontium titanite), BT (barium titanite), BZT (barium zirconium titanite), aluminum nitrate, etc. Most of the examples herein are described with regard to PZT, which may be applied on the order of 1-3 μm in thickness.

An electrical voltage may be applied between insulator-adjacent electrode 112 and insulator-distal electrode 116. This voltage differential translates to an electric field, which is turn caused actuation in piezo layer 114. Piezo layer 114 will then expand with the introduction of electric fields, typically normal to insulator layer 104, and introduce in-plane actuation force through introduced tensile strain due to the Poisson ratio of the piezo material. PZT and PNZT have the advantage of being highly efficient actuation materials, compared with aluminum nitrite for example, which has a much smaller peak shrinkage in piezo activation than that of PZT.

FIG. 1B shows a piezoelectric actuator assembly 120 that incorporates piezoelectric actuator 100. A wire routing layer 122 is positioned on the piezo actuator stack 110 so as to extend along a sidewall of piezo layer 114. Wire routing layer 122 includes a passivation layer 124 which may be used as a wiring insulator, and wiring 126. Passivation layer 124 may be an insulating layer, such as an oxide or nitride layer on the order of 0.5 μm in thickness, for example. Passivation layer 124 may increase reliability of piezoelectric actuator assembly 120 in any applications in which piezo actuator stack 110 is exposed to humidity.

Passivation layer 124 may expose portions of insulator-adjacent electrode 112 and insulator-distal electrode 116 to allow for contact pads 128 and 130 to bond wiring 126 to the electrodes. Contact pads 128 and 130 may be provided for applying voltages to insulator-adjacent electrode 112 and insulator-distal electrode 116.

Wiring 126 may extend down from insulator-distal electrode 116 over passivation layer 124 to prevent insulator-distal electrode 116 from shorting to the insulator-adjacent electrode 112 and to insulate the side wall of insulator-distal electrode 116 from the wiring contact point at contact pad 130. Wiring 126 and contact pads 128 and 130 may be formed of suitable conductive metal films e.g., platinum, aluminum, Ti/Pt multilayered films, etc. but are not necessarily made from the same material.

Piezo actuation is proportional to the applied voltage or drive signal across insulator-adjacent electrode 112 and insulator-distal electrode 116. In this example, piezo layer 114 may expand away from substrate 102, then contract when the voltage is removed or reversed. Many piezoelectric materials expand in one direction and contract in one or two other directions and, therefore, generate stress in substantially all directions when activated which may cause significant dimensional changes in accompanying structures. For example, high strain region 132 includes portions of passivation layer 124 and wiring 126 which extend over the sidewall of piezo layer 114 and thus experience significant strain each time piezo layer 114 translates. Such mating films may experience cyclic stress over numerous rounds of actuation, leading to mechanical fatigue failures over time.

As such, the dimensional changes of the piezo actuator causes corresponding dimensional changes that strain the neighboring and supporting components. In scenarios where those components are being repeatedly dimensionally stressed, the piezoelectric actuator assembly may experience long term reliability problems.

As such, this disclosure provides a piezo layer sidewall that improves long term reliability. One approach to this is to design the piezo actuator so that deformation of the piezo layer occurs gradually, over a long distance, thus reducing the greatest local strain values. As an example, this can be achieved by tapering the piezo layer sidewall and providing mating layers such as wiring only over the tapered sidewall. In this way, the tapered sidewall determines the deformation area of the piezo actuator stack. Additionally or alternatively, the edge of the insulator-distal electrode can be offset from the piezo layer sidewall. In this way, actuation strain is further reduced at the sidewall as the insulator-distal electrode defines the actuation profile of the piezo layer.

Sidewall tapering is thought to lead to increased reliability of the wire bonding, piezo layer reliability points, and piezoelectric actuator mating films, including passivation, inter-layer dielectric, and step cross wiring cases. Such piezo actuator stack structures may thus increase reliability and can occupy a reduced footprint in MEMS devices. Further performance enhancements may include increasing the electrical leakage path, thus decreasing breakdown voltage, and enabling greater step coverage and increased reliability for metal film deposition, especially for physical vapor deposition of such films.

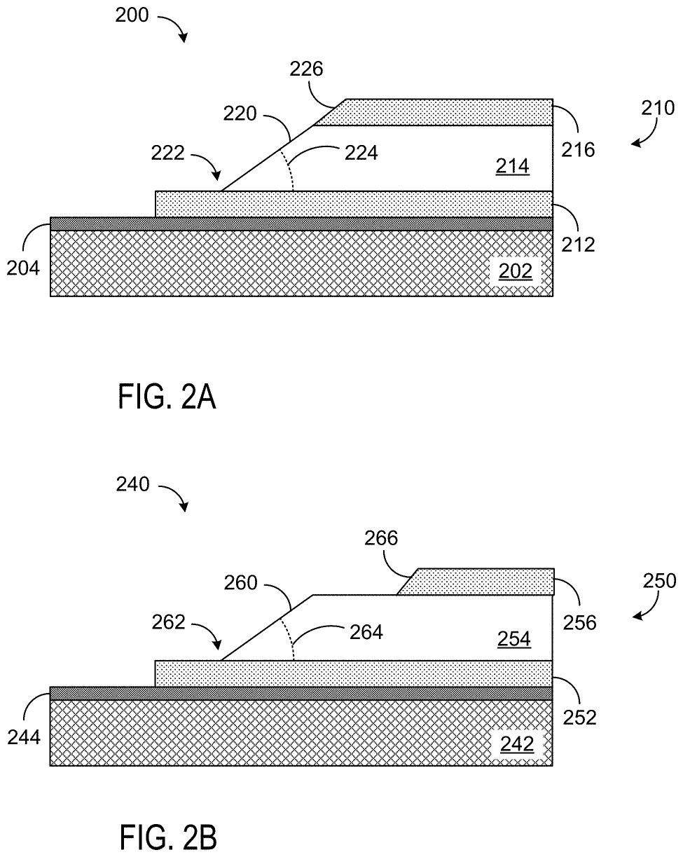

FIG. 2A schematically shows a cross section of an embodiment of a piezoelectric actuator 200 including a tapered sidewall. Piezoelectric actuator includes a substrate 202, an insulator layer 204 on substrate 202, and a piezo actuator stack 210 on insulator layer 204. Substrate 202 and insulator layer 204 may be examples of substrate 102 and insulator layer 104. Piezo actuator stack 210 includes three layers—an insulator-adjacent electrode 212 on insulator layer 204, a piezo layer 214 on at least a portion of the insulator-adjacent electrode 212, and an insulator-distal electrode 216 on at least a portion of piezo layer 214.

Piezo actuator stack 210 is an example actuator stack wherein piezo layer 214 has a tapered sidewall 220. In this example, piezo layer 214 does not extend the length of insulator-adjacent electrode 212, rather, tapered sidewall 220 forms an intersection 222 with insulator-adjacent electrode 212 at the tapering angle 224.

In this example, insulator-distal electrode 216 has a taper-adjacent edge 226 that is offset from intersection 222, extending to an edge of tapered sidewall 220. In this example, taper-adjacent edge 226 of insulator-distal electrode 216 is tapered at a same tapering angle 224 as tapered sidewall 220 of piezo layer 214. However, in other examples, taper adjacent edge 226 may have a smaller tapering angle or larger tapering angle, or may not taper at all (e.g., 90°).

Piezo layer 214 may be formed using a dry etching technique. In this way, tapering angle 224 can be controlled. As tapering angle 224 decreases, less strain is induced on overlayed components. However, using a small angle generates a more significant region where the voltage differential is reduced and thus there is either less expansion of piezo layer 214 or significant wasted spacing. As such, the packaging constraints of the device incorporating piezoelectric actuator 200 may constrain tapering angle 224. Tapering angle 224 may be selected to be greater than or equal to 30° and less than or equal to 60°, as examples. By selecting a tapering angle in this range, the size of the insulator-distal electrode 216 can be maintained with only modest reductions in actuation strength.

FIG. 2B schematically shows a cross section of another embodiment of a piezoelectric actuator 240 of the current disclosure. Piezoelectric actuator 240 includes a substrate 242, an insulator layer 252 on substrate 242, and a piezo actuator stack 250 on insulator layer 252. Substrate 202 and insulator layer 204 may be examples of substrate 102 and insulator layer 104. Piezo actuator stack 250 includes three layers—an insulator-adjacent electrode 252 on insulator layer 204, a piezo layer 254 on at least a portion of the insulator-adjacent electrode 252, and an insulator-distal electrode 256 on at least a portion of piezo layer 254.

As per FIG. 2A, piezo actuator stack 250 is an example actuator stack wherein piezo layer 254 has a tapered sidewall 260 that forms an intersection 262 with insulator-adjacent electrode 252 at the tapering angle 264. In this example, insulator-distal electrode 216 has a taper-adjacent edge 266 that is offset from tapered sidewall 260. In this example, taper-adjacent edge 266 of insulator-distal electrode 256 is tapered at a same tapering angle 264 as the tapered sidewall 260, although this is not required.

With the additional offset of insulator-distal electrode 256, tapering angle 264 may be steeper that tapering angle 224, for example tapering angle 264 selected to be less than or equal to 80°. The offset distance itself is dependent primarily on microfabrication limitations, and how well the layers of piezoelectric stack can be aligned, generally on the order of 0.5-3 μm.

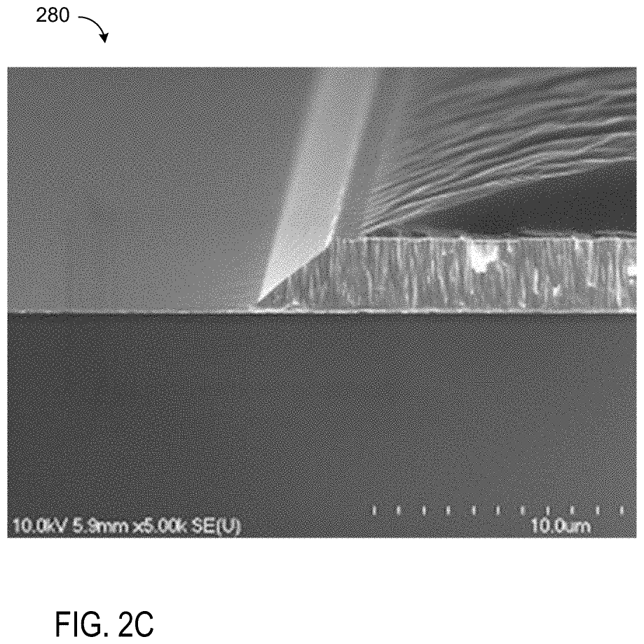

In this example, tapering angle 264 can be controlled, and insulator-distal electrode 256 may still be offset from piezo layer 254. The offset cross section serves to further reduce the strains on overlayed structures, as discussed further herein and with regard to FIGS. 3A-3C. In either example, piezoelectric actuators 200 and 240 allow for wiring down over tapered sidewalls 220 and 260, respectively. This enables greater physical vapor deposition (PVD) film step coverage for metal wiring and allows for reliable bonding of the wiring to electrode pads. As an example, FIG. 2C shows an example scanning electron microscope image 280 of a piezo layer during a manufacturing stage, the piezo layer having a tapered sidewall with a smoothly tapered reflown photoresist mask still in place.

The inclusion of a piezo layer with a tapered sidewall, and additionally, the offsetting on the insulator-distal electrode from the edge of the piezo layer serves to improve step coverage and reliability of overlaying componentry. Examples are shown in FIGS. 3A-3C. FIG. 3A shows an example piezoelectric actuator assembly 300, which includes piezoelectric actuator 100, and further includes a strain-sensitive layer 305 formed on piezo actuator stack 110. Strain-sensitive layer 305 may include passivation and wiring layers. As described with regard to FIG. 1A, piezo layer 114 has an untapered sidewall (e.g., 90°). Actuation (e.g., PZT thickness growth) due to applied voltage is shown by dashed arrows within piezo layer 114. Accordingly, the strain field and resulting deformation due to applied electric field of strain-sensitive layer 305 is mostly generated at 310 (solid arrow), wherein strain-sensitive layer 305 extends from insulator-adjacent electrode 112 to insulator-distal electrode 116. This strain field is normal to substrate 102, and may be considered to be directly proportional to the PZT deformation on the sidewall.

FIG. 3B shows an example piezoelectric actuator assembly 320, which includes piezoelectric actuator 200, and further includes a strain-sensitive layer 325 formed on piezo actuator stack 210. Strain-sensitive layer 325 extends along tapered sidewall 220 of piezo layer 214 and along taper-adjacent edge 226 of insulator-distal electrode 216. Actuation due to applied voltage is shown by dashed arrows within piezo layer 214, increasing as the thickness of piezo layer 214 increases, and as piezo layer 214 is covered completely by insulator-distal electrode 216. Accordingly, the strain field and resulting deformation due to applied electric field of strain-sensitive layer 305 is generated at 330 (solid arrow), along tapered sidewall 220 and taper-adjacent edge 226. The strain field shown at 330 is reduced as compared to the strain field shown at 310 of FIG. 3A, and is scaled down based on the tapering angle.

FIG. 3C shows an example piezoelectric actuator 340, which includes piezoelectric actuator 240, and further includes a strain-sensitive layer 345 formed on piezo actuator stack 250. Strain-sensitive layer 345 extends along tapered sidewall 260 of piezo layer 254 and along taper-adjacent edge 266 of insulator-distal electrode 256. Actuation due to applied voltage is shown by dashed arrows within piezo layer 254, increasing as the thickness of piezo layer 214 increases, and further increasing as piezo layer 254 is covered completely by insulator-distal electrode 256. Accordingly, the strain field and resulting deformation due to applied electric field of strain-sensitive layer 305 is generated at 350 (solid arrow), along taper-adjacent edge 266 and a neighboring surface of piezo layer 254. The strain field shown at 350 is reduced even further as compared to the strain field shown at 330 of FIG. 3B. This results in a low tensile and bending field.

The reduction in the strain may be considered a dimensionality problem, where the dimensional change in the piezo layer is normal to the insulator-adjacent electrode. When that vector is applied on the tapering angle, the strain-sensitive layer experiences less stretch per unit length, expanding the deformation zone over a wider region. By offsetting the insulator-distal electrode, the dimensional change of the piezo actuator is further reduced along the tapered sidewall, diminishing the deformation zone in this region.

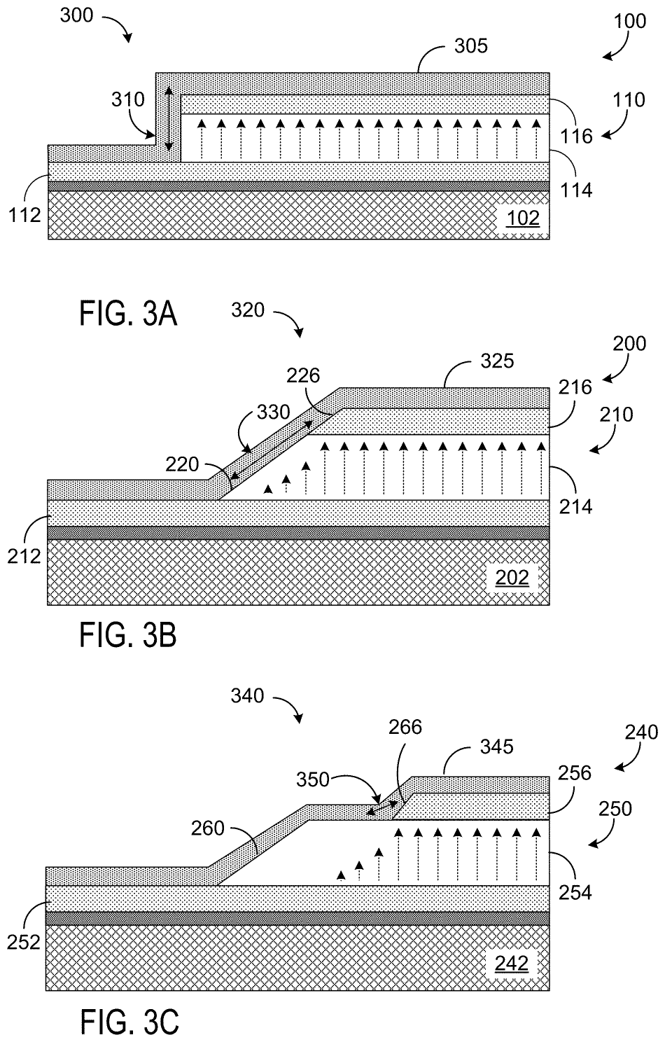

Further, the tapered sidewalls can allow greater step coverage with which to introduce a passivation layer on the piezo actuator stack. Controlling the tapering angle enables the wiring that is routed from the insulator-distal electrode over the piezo actuator stack to ground to be less stretched and/or less stressed, and thus result in fewer fatigue failures. An example is shown in FIG. 4.

FIG. 4 shows an example piezoelectric actuator assembly 400, including piezoelectric actuator 240 as described with regards to FIGS. 2B and 3C. Wire routing layer 405 is formed on piezo actuator stack 250. Wire routing layer 405 includes passivation layer 410 and wiring 415. When wiring 415 is metallic in nature, it may face mechanical fatigue behavior from repeated mechanical strain fields extending on to it. Two tapered sidewalls (260a and 260b) of piezo layer 254 are shown. Similarly, two taper-adjacent edges (266a and 266b) of insulator-distal electrode 256 are shown. Wiring 415 is routed down over tapered sidewall 260b via passivation layer 410. Wiring 415 is electrically coupled to insulator-adjacent electrode 252 via pad 418 and to insulator-distal electrode 256 via pad 420.

When adding the insulator-distal electrode ground contact and routing down on an exterior surface of passivation layer 410, the electric field becomes divided. The primary electric field, shown at 422, is generated between the two electrodes (252 and 256). There is also a secondary electric field, shown at 424, generated from wiring 415 routing between insulator-adjacent electrode 252 and insulator-distal electrode 256.

In this embodiment, insulator-distal electrode 256 is offset not only from tapered edges 260a and 260b, but from insulator-adjacent electrode 252. As such, a portion of piezo layer 254, exposed region 426, is not positioned directly in between insulator-adjacent electrode 252 and insulator-distal electrode 256. This portion (shown at 428) of primary electric field 422 within exposed region 426 is reduced.

Secondary electric field 424, generated between wiring 415 and insulator-adjacent electrode 252, penetrates passivation layer 410 over tapered sidewall 260b. However, secondary electric field 424 minimally excites piezo layer 254, due to the low dielectric constant value (ϵᵣ) of passivation layer 410. As an example, ϵᵣ for PZT is 1000, while ϵᵣ for SiO₂ is 3.9. As such, the total electric field over exposed region 426 is split between inert passivation layer 410 and piezo layer 254, and thus piezo layer 254 may not significantly move within exposed region 426 when actuated. As a result, the strain induced by actuation of piezo layer 254 is reduced, because only a portion of piezo layer 254 significantly translates, and translation of wiring 415 is reduced.

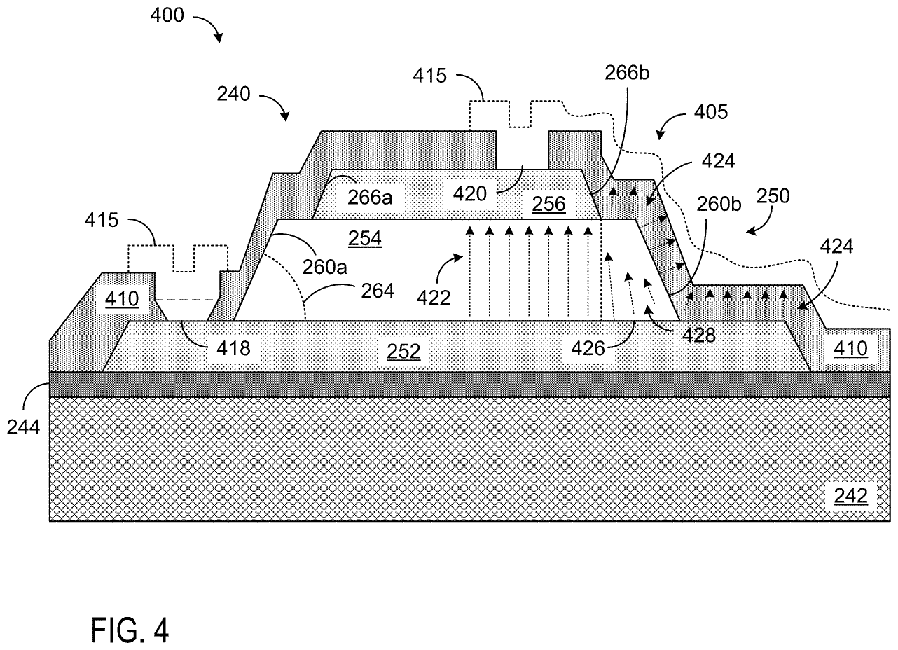

FIG. 5 depicts an example method 500 of manufacturing a piezoelectric actuator. For example, method 500 may be utilized in the manufacturing of piezoelectric actuators 200 and 240. At 510, method 500 includes forming an insulator layer on a substrate, the insulator layer including one or more of an insulating oxide layer and an adhesion promoter layer. The substrate may be a silicon wafer, for example. As an example, a layer of an insulating oxide, such as silicon dioxide having a thickness on the order of 0.1-1 μm may be formed on the substrate. An adhesion promoter layer, such as TiO₂, Ti, TiW, etc. may be applied to promote adhesion of electrodes to the substrate and/or the insulating oxide. Continuing at 520, method 500 includes forming an insulator-adjacent electrode on the insulator layer. The insulator-adjacent electrode may include a single layer or a plurality of layers of conductive material. For example, insulator-adjacent electrode may be applied as a thin, (0.1 μm) conductive films made of single layer of platinum, palladium, iridium, etc., or multilayered films such as Ti/Pt films.

At 530, method 500 includes forming a piezo layer on a portion of the insulator-adjacent electrode. The piezo layer may be any suitable piezoelectric ceramic material, such as PZT, PNZT, aluminum nitrate, etc., and may be applied on the order of 1-3 μm in thickness, such as a piezoelectric film. Continuing at 540, method 500 includes forming an insulator-distal electrode on the piezo layer, the insulator-distal electrode may have the same, or similar material composition and thickness as the insulator-adjacent electrode. Any of the described layers may be applied through the use of appropriate methods, such as thin film patterning techniques utilizing resist films, and wet or dry etching techniques, including lift-off patterning.

At 550, method 500 includes patterning the insulator-distal electrode. The insulator-distal electrode may be patterned through dry-etching and/or through any suitable anisotropic etching process. Continuing at 560, method 500 includes patterning the piezo layer to have a tapered sidewall. The piezo layer may be patterned concurrently with the insulator-distal electrode or may be pattern subsequently. As a result of the patterning process(es), the insulator-distal electrode may have a taper-adjacent edge offset from an intersection of the tapered sidewall of the piezo layer and the insulator-adjacent electrode.

Although more expensive to execute, dry etching of the piezo layer may be used as opposed to wet etching, which produces more or less vertical sidewalls, depending on the material properties, such as whether the crystal orientation within the piezoelectric film is columnar, homogeneous, etc. Dry etching allows for control over the tuning of the patterning profile such as shown in FIG. 2C, where the piezo layer forms a tapered, thinning down wall at the patterning edges. Any suitable dry etching technique may be used, such as reactive ion etching, plasma etching, inductively coupled plasma etc. As described with regards to FIGS. 2A and 2B, in some examples, the tapered sidewall forms a tapering angle with the insulator-adjacent electrode that is selected to be less than or equal to 80°. In a subset of such examples, the tapering angle may be selected to be greater than or equal to 30° and less than or equal to 80°. The insulator-adjacent electrode may be patterned following the patterning of the piezo layer.

Optionally, at 570, method 500 includes forming a passivation layer on at least the insulator-adjacent electrode, the piezo layer, and the insulator-distal electrode, such that the passivation layer exposes portions of the insulator-adjacent electrode and the insulator-distal electrode to form wiring contacts, and such that the passivation layer includes routing along the tapered sidewall of the piezo layer.

Optionally, at 580, method 500 includes forming wiring on at least the routing of the passivation layer and the wiring contacts, for example by physical vapor deposition. Wiring may be a conductive metal such as platinum films, the same or similar conductive material as the insulator-adjacent and insulator-distal electrode, other single material films, multi-layered films (e.g., Ti/Ni/Au), for example with a thickness on the order of 50-250 nm.

Such piezoelectric actuators may be packaged into parent devices, such as a MEMS in any suitable fashion. For example, a piezoelectric actuator assembly may be bonded onto a housing and then coupled to the electrical wiring for the parent device by wire bonding or soldering or thermocompression.

As an example use-case scenario, the above described piezoelectric actuators may be incorporated into MEMS scanning devices. MEMS scanning devices modulate the angular position of a scanning mirror with extremely high accuracy by applying controlled electric fields to piezoelectric actuators that have been deposited over top and/or bottom surfaces of actuator plates that are mechanically coupled to the scanning mirror. As a piezoelectric actuator expands or contracts, mechanical stress is induced at whichever surface of the actuator plate the piezoelectric film is attached. This mechanical stress generates a bending moment within the actuator plate which causes longitudinal curvature that results in an actuator stroke. Through persistent actuation of the piezoelectric actuators, the MEMS scanning devices may operate at a high frequency rate with high accuracy. This may place typical piezoelectric actuator assemblies, such piezoelectric actuator assembly 120 as described with regard to FIG. 1B at risk for stress and strain induced fatigue and failure. By implementing piezoelectric actuator assemblies such as piezoelectric actuator assembly 400, the devices may be more reliable over time.

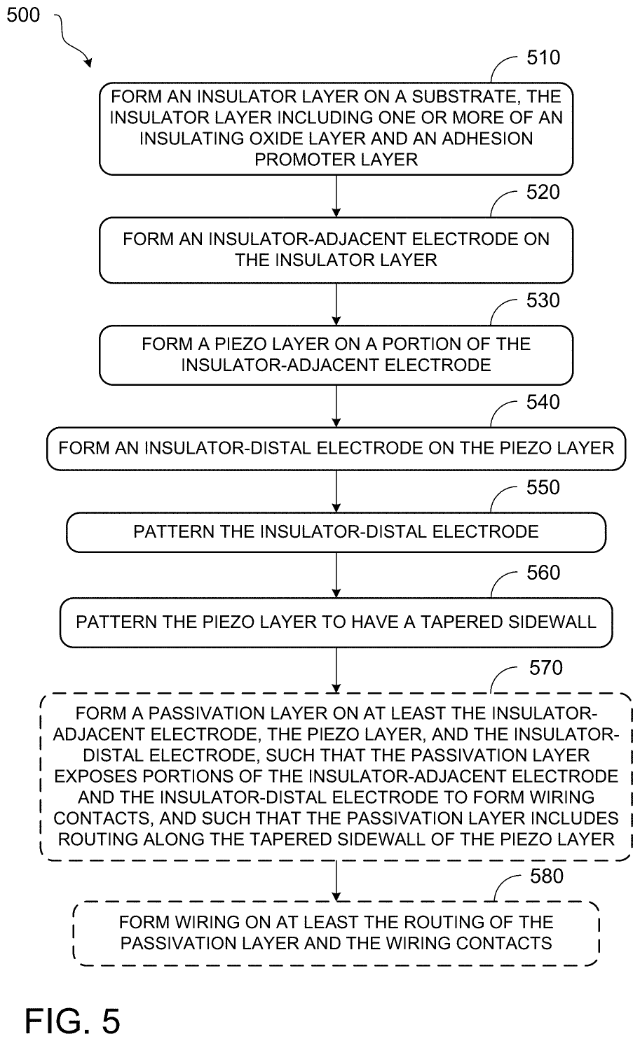

Turning now to FIG. 6, illustrated is a block diagram of an exemplary control system 600 for a MEMS 604 that includes one or more piezoelectric actuators 606 having various geometric details as described herein. For example, piezoelectric actuators 200 and 240 may be examples of piezoelectric actuators 606. As illustrated in FIG. 6, the control system 600 may include a controller 602 that provides drive signals 610 to one or more piezoelectric actuators 606 as described herein. The piezoelectric actuators 606 may be configured to controllably move various components and/or subdevices of the MEMS 604 relative to a platform. As further illustrated, the control system 600 further includes strain sensors 608 that detect certain modes of mechanical strain within the MEMS 604 and, in response thereto, provide a feedback signal 612 to the controller 602. An exemplary strain sensor 608 may comprise a piezoresistive (PZR) sensor that transduces mechanical movement of a specific portion of the MEMS 604 into an electrical signal to generate the feedback signal 612. As such, MEMS 604 may be any type of MEMS device that operates electromechanically in response to a drive signal 610 while optionally returning a feedback signal 612 to facilitate periodic and/or continual refinement of the drive signal 610.

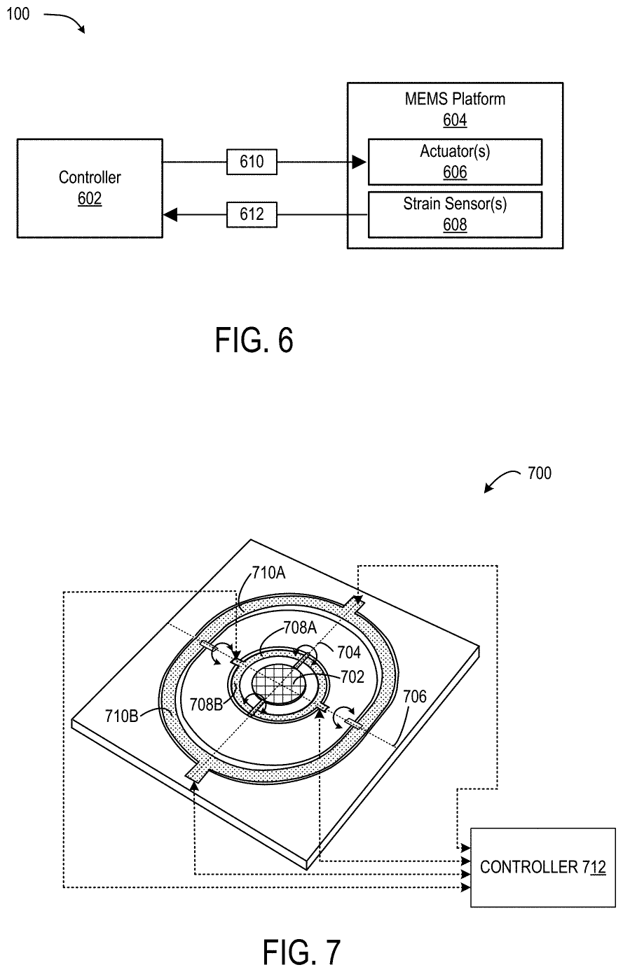

As an example, MEMS 604 may be a scanning mirror system, such as a dual axis scanning mirror. FIG. 7 shows a non-limiting example of a resonant scanning mirror system 700. The resonant scanning mirror system 700 comprises a scanning mirror 702 that is supported along two orthogonally pivoting axes 704, 706. Vertical scan and horizontal scan are controlled via mirror drive elements that pivot the scanning mirror 702 about the axes 704, 706. In this example, the first mirror drive element comprises a first piezoelectric actuator assembly 708A and a second piezoelectric actuator assembly 708B, which are operable to drive the mirror in a first scan direction via harmonic oscillation. This scan direction can be referred to as a fast scan direction. In the fast scan direction, the mirror scans a beam of light in a sinusoidal manner at a relatively higher frequency. The second mirror drive element comprises a third piezoelectric actuator 710A and a fourth piezoelectric actuator 710B, which drive the mirror in a second scan direction orthogonal to the first scan direction. This scan direction can be referred to as a slow scan direction. In the slow scan direction, the mirror can be driven via a control signal having a sawtooth-type nature, such that the mirror angle changes more slowly while the beam of light is scanned back and forth in the fast direction to scan an image. Upon completion of scanning an image, the resonant scanning mirror system 700 resets more quickly in the slow scan direction (e.g., following a steeper portion of a sawtooth-like control signal) to begin scanning a next image. Piezoelectric actuator assembly 400 may be an example of piezoelectric actuator assemblies 708A-708B and 710A-710B. The supports on which the piezo actuator assemblies are positioned are subject to the highest bending forces, and thus piezo resistive strain sensors (not shown) may also be positioned at these supports, with appropriate wiring to controller 712 to provide strain feedback.

The first and second mirror drive elements 708A, 708B for the fast scan direction are driven by 180 degree out-of-phase sinusoidal signals. By applying oscillating electrical alternating current (AC) voltages to the respective drive elements, the scanning mirror 702 is caused to oscillate, thereby causing appropriate scanning to occur. Scanning mirror 702 may indeed rotate significantly, on the order of 20-40° of the normal angle. Such oscillation can be efficiently obtained and maintained based on the first and second drive elements 708a, 708b being driven at a mechanical resonant frequency of the resonant scanning mirror system 700 in the fast scan direction.

In one example, a piezoelectric actuator comprises a substrate; an insulator layer on the substrate; a piezo actuator stack on the insulator layer, the piezo actuator stack comprising an insulator-adjacent electrode on the insulator layer; a piezo layer having a tapered sidewall on a portion of the insulator-adjacent electrode; and an insulator-distal electrode on the piezo layer having a taper-adjacent edge offset from an intersection of the tapered sidewall of the piezo layer and the insulator-adjacent electrode. In such an example, or any other example, the piezoelectric actuator additionally or alternatively comprises a wire routing layer on the piezo actuator stack extending along the tapered sidewall of the piezo layer. In any of the preceding examples, or any other example, the wire routing layer additionally or alternatively includes a passivation layer that exposes portions of the insulator-adjacent electrode and the insulator-distal electrode to form wiring contacts; and wiring extending from the insulator-distal electrode through routing of an exterior surface of the passivation layer so that the wiring extends along the tapered sidewall of the piezo layer. In any of the preceding examples, or any other example, the taper-adjacent edge of the insulator-distal electrode is additionally or alternatively tapered at a same angle as the tapered sidewall of the piezo layer. In any of the preceding examples, or any other example, the tapered sidewall additionally or alternatively forms an angle with the insulator-adjacent electrode that is selected to be greater than or equal to 30° and less than or equal to 60°. In any of the preceding examples, or any other example, the taper-adjacent edge of the insulator-distal electrode is additionally or alternatively offset from the tapered sidewall of the piezo layer. In any of the preceding examples, or any other example, the tapered sidewall additionally or alternatively forms an angle with the insulator-adjacent electrode that is selected to be less than or equal to 80°.

In another example, a micro-electrical mechanical system comprises a controller configured to provide drive signals to one or more piezo electric actuators, each piezoelectric actuator comprising: a substrate; an insulator layer on the substrate; a piezo actuator stack on the insulator layer, the piezo actuator stack comprising; an insulator-adjacent electrode on the insulator layer; a piezo layer having a tapered sidewall on a portion of the insulator-adjacent electrode; and an insulator-distal electrode on the piezo layer having a taper-adjacent edge offset from an intersection of the tapered sidewall of the piezo layer and the insulator-adjacent electrode. In such an example, or any other example, each piezoelectric actuator additionally or alternatively comprises a wire routing layer on the piezo actuator stack extending along the tapered sidewall of the piezo layer. In any of the preceding examples, or any other example, the wire routing layer additionally or alternatively includes: a passivation layer that exposes portions of the insulator-adjacent electrode and the insulator-distal electrode to form wiring contacts; and wiring extending from the insulator-distal electrode through routing of an exterior surface of the passivation layer so that the wiring extends along the tapered sidewall of the piezo layer. In any of the preceding examples, or any other example, the taper-adjacent edge of the insulator-distal electrode is additionally or alternatively tapered at a same tapering angle as the tapered sidewall of the piezo layer. In any of the preceding examples, or any other example, the tapering angle is additionally or alternatively selected to be greater than or equal to 30° and less than or equal to 60°. In any of the preceding examples, or any other example, the taper-adjacent edge of the insulator-distal electrode is additionally or alternatively offset from the tapered sidewall of the piezo layer. In any of the preceding examples, or any other example, the tapered sidewall additionally or alternatively forms a tapering angle with the insulator-adjacent electrode that is selected to be less than or equal to 80°. In any of the preceding examples, or any other example, the micro-electrical mechanical system additionally or alternatively comprises a scanning mirror system, wherein each scanning mirror is driven via one or more mirror drive elements, each mirror drive element comprising two or more of the piezoelectric actuators.

In yet another example, a method of manufacturing a piezoelectric actuator comprises forming an insulator layer including one or more of an insulating oxide layer and an adhesion promoter layer on a substrate; forming an insulator-adjacent electrode on the insulator layer; forming a piezo layer on a portion of the insulator-adjacent electrode; forming an insulator-distal electrode on the piezo layer; patterning the insulator-distal electrode; and patterning the piezo layer to have a tapered sidewall. In such an example, or any other example, patterning the piezo layer to have the tapered sidewall additionally or alternatively includes dry etching the piezo layer. In any of the preceding examples, or any other example, the method of manufacturing additionally or alternatively comprises patterning the insulator-distal electrode to have a taper-adjacent edge offset from an intersection of the tapered sidewall of the piezo layer and the insulator-adjacent electrode. In any of the preceding examples, or any other example, the method additionally or alternatively comprises forming a passivation layer on at least the insulator-adjacent electrode, the piezo layer, and the insulator-distal electrode, such that the passivation layer exposes portions of the insulator-adjacent electrode and the insulator-distal electrode to form wiring contacts, and such that the passivation layer includes routing along the tapered sidewall of the piezo layer. In any of the preceding examples, or any other example, a tapering angle of the tapered sidewall is additionally or alternatively selected to be greater than or equal to 30° and less than or equal to 80°.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A piezoelectric actuator, comprising:
a substrate;
an insulator layer on the substrate;
a piezo actuator stack on the insulator layer, the piezo actuator stack comprising;
an insulator-adjacent electrode on the insulator layer;
a piezo layer having a tapered sidewall on a portion of the insulator-adjacent electrode; and
an insulator-distal electrode on the piezo layer having a taper-adjacent edge offset from an intersection of the tapered sidewall of the piezo layer and the insulator-adjacent electrode.

2. The piezoelectric actuator of claim 1, further comprising:
a wire routing layer on the piezo actuator stack extending along the tapered sidewall of the piezo layer.

3. The piezoelectric actuator of claim 2, wherein the wire routing layer includes:
a passivation layer that exposes portions of the insulator-adjacent electrode and the insulator-distal electrode to form wiring contacts; and
wiring extending from the insulator-distal electrode through routing of an exterior surface of the passivation layer so that the wiring extends along the tapered sidewall of the piezo layer.

4. The piezoelectric actuator of claim 1, wherein the taper-adjacent edge of the insulator-distal electrode is tapered at a same angle as the tapered sidewall of the piezo layer.

5. The piezoelectric actuator of claim 4, wherein the tapered sidewall forms an angle with the insulator-adjacent electrode that is selected to be greater than or equal to 30° and less than or equal to 60°.

6. The piezoelectric actuator of claim 1, wherein the taper-adjacent edge of the insulator-distal electrode is offset from the tapered sidewall of the piezo layer.

7. The piezoelectric actuator of claim 6, wherein the tapered sidewall forms an angle with the insulator-adjacent electrode that is selected to be less than or equal to 80°.

8. A micro-electrical mechanical system, comprising:
a controller configured to provide drive signals to one or more piezo electric actuators, each piezoelectric actuator comprising:
a substrate;
an insulator layer on the substrate;
a piezo actuator stack on the insulator layer, the piezo actuator stack comprising;
an insulator-adjacent electrode on the insulator layer;
a piezo layer having a tapered sidewall on a portion of the insulator-adjacent electrode; and
an insulator-distal electrode on the piezo layer having a taper-adjacent edge offset from an intersection of the tapered sidewall of the piezo layer and the insulator-adjacent electrode.

9. The micro-electrical mechanical system of claim 8, wherein each piezoelectric actuator further comprises:
a wire routing layer on the piezo actuator stack extending along the tapered sidewall of the piezo layer.

10. The micro-electrical mechanical system of claim 9, wherein the wire routing layer includes:
a passivation layer that exposes portions of the insulator-adjacent electrode and the insulator-distal electrode to form wiring contacts; and
wiring extending from the insulator-distal electrode through routing of an exterior surface of the passivation layer so that the wiring extends along the tapered sidewall of the piezo layer.

11. The micro-electrical mechanical system of claim 8, wherein the taper-adjacent edge of the insulator-distal electrode is tapered at a same tapering angle as the tapered sidewall of the piezo layer.

12. The micro-electrical mechanical system of claim 11, wherein the tapering angle is selected to be greater than or equal to 30° and less than or equal to 60°.

13. The micro-electrical mechanical system of claim 8, wherein the taper-adjacent edge of the insulator-distal electrode is offset from the tapered sidewall of the piezo layer.

14. The micro-electrical mechanical system of claim 13, wherein the tapered sidewall forms a tapering angle with the insulator-adjacent electrode that is selected to be less than or equal to 80°.

15. The micro-electrical mechanical system of claim 8, further comprising a scanning mirror system, wherein each scanning mirror is driven via one or more mirror drive elements, each mirror drive element comprising two or more of the piezoelectric actuators.

16. A method of manufacturing a piezoelectric actuator, comprising:
forming an insulator layer including one or more of an insulating oxide layer and an adhesion promoter layer on a substrate;
forming an insulator-adjacent electrode on the insulator layer;
forming a piezo layer on a portion of the insulator-adjacent electrode;
forming an insulator-distal electrode on the piezo layer;
patterning the insulator-distal electrode; and
patterning the piezo layer to have a tapered sidewall.

17. The method of manufacturing of claim 16, wherein patterning the piezo layer to have the tapered sidewall includes dry etching the piezo layer.

18. The method of manufacturing of claim 16, further comprising:
patterning the insulator-distal electrode to have a taper-adjacent edge offset from an intersection of the tapered sidewall of the piezo layer and the insulator-adjacent electrode.

19. The method of manufacturing of claim 16, further comprising:
forming a passivation layer on at least the insulator-adjacent electrode, the piezo layer, and the insulator-distal electrode, such that the passivation layer exposes portions of the insulator-adjacent electrode and the insulator-distal electrode to form wiring contacts, and such that the passivation layer includes routing along the tapered sidewall of the piezo layer.

20. The method of manufacturing of claim 16, wherein a tapering angle of the tapered sidewall is selected to be greater than or equal to 30° and less than or equal to 80°.
